(19) United States
(12) Patent Application Publication
(10) Pub. No.: US 2020/0409436 A1
(43) Pub. Date: Dec. 31, 2020

(54) ELECTRONIC APPARATUS

(71) Applicant: LENOVO (SINGAPORE) PTE. LTD., SINGAPORE (SG)

(72) Inventors: Ryota Watanabe, YOKOHAMA (JP); Akinori Uchino, YOKOHAMA (JP); Osamu Yamamoto, YOKOHAMA (JP); Takuroh Kamimura, YOKOHAMA (JP)

(73) Assignee: LENOVO (SINGAPORE) PTE. LTD., SINGAPORE (SG)

(21) Appl. No.: 16/591,409

(22) Filed: Oct. 2, 2019

(30) Foreign Application Priority Data
Jun. 27, 2019 (JP) 2019119455

(51) Int. Cl. G06F 1/20; H05K 7/14; H01Q 1/22

(52) U.S. Cl. CPC G06F 1/203; H01Q 1/2266; H05K 7/1445

(57) ABSTRACT

An electronic apparatus includes: a chassis with an air outlet provided on a first side surface thereof; a cooling fan housed in the chassis; a duct lying between an air outlet of the cooling fan and the air outlet of the chassis; and an electronic component mounted on the duct.

### FIELD OF THE INVENTION

The present invention relates to an electronic apparatus.

### BACKGROUND OF THE INVENTION

An electronic apparatus such as a portable laptop personal computer includes a cooling fan that discharges heat radiating from electronic components in a chassis to the outside through an air outlet provided on a side surface of the chassis (see, for example, Japanese Unexamined Patent Application Publication No. 2011-227925).

### SUMMARY OF THE INVENTION

In recent years, in response to request for thinner electronic apparatuses, chassis of electronic apparatuses are thin and densely packed with electronic components, and their airflow impedance (flow path resistance) becomes higher. Accordingly, it is conceivable that an air outlet of a cooling fan and an air outlet of a chassis are connected by a duct so as not to hinder an exhaust air flow of the cooling fan. However, various electronic components, such as an antenna, I/O ports, and a speaker, are disposed in a peripheral edge of the chassis along a side surface of the chassis where the air outlet is provided, and thus there are restrictions on the freedom of layout.

The present invention has been made in view of the above-described problems, and is intended to provide an electronic apparatus that does not hinder an exhaust air flow of a cooling fan while easing restrictions on the freedom of layout of electronic components in a peripheral edge of a chassis.

To resolve the above-described problems, an electronic apparatus according to an aspect of the present invention includes: a chassis with an air outlet provided on a first side surface thereof; a cooling fan housed in the chassis; a duct lying between an air outlet of the cooling fan and the air outlet of the chassis; and an electronic component mounted on the duct.

Furthermore, in the above-described electronic apparatus, the electronic component may be a planar wireless LAN antenna.

Moreover, in the above-described electronic apparatus, an air intake may be provided on a second side surface of the chassis that is a different side surface from the first side surface.

Furthermore, in the above-described electronic apparatus, the cooling fan may be disposed in a corner of the chassis formed by the first side surface and the second side surface.

Moreover, in the above-described electronic apparatus, the duct and the electronic component may be disposed in a peripheral edge of the chassis along the first side surface.

The above-described aspect of the present invention can provide an electronic apparatus that does not hinder an exhaust air flow of a cooling fan while easing restrictions on the freedom of layout of electronic components in a peripheral edge of a chassis.

### BRIEF DESCRIPTION OF THE DRAWINGS

FIG. 1 is a perspective view of an electronic apparatus according to an embodiment of the present invention.

FIG. 2 is a plan view of the electronic apparatus shown in FIG. 1 when its chassis extends at an angle of 180 degrees.

FIG. 3 is a cross-sectional plan view showing respective configurations of a cooling fan and a duct in the embodiment of the present invention.

FIG. 4 is a view on an arrow A-A shown in FIG. 3.

### DETAILED DESCRIPTION OF THE INVENTION

An embodiment of the present invention is described below with reference to drawings.

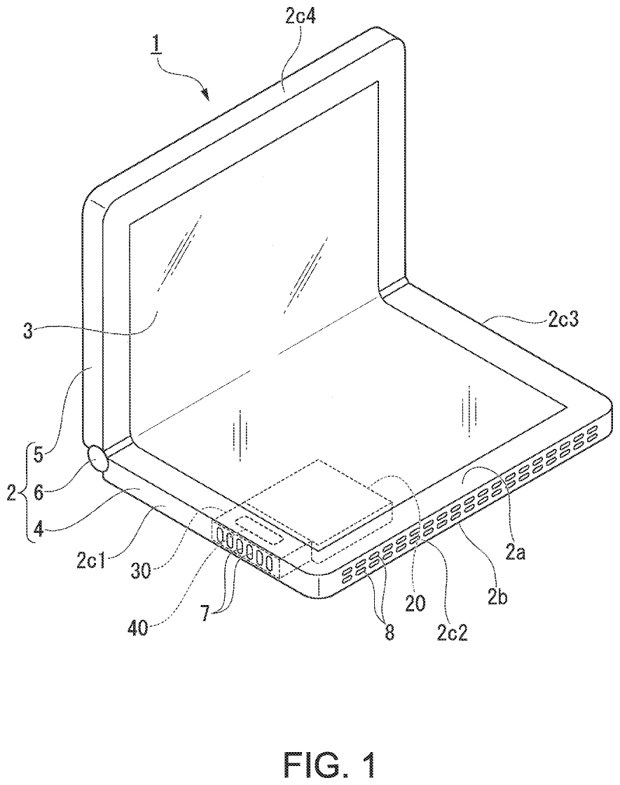

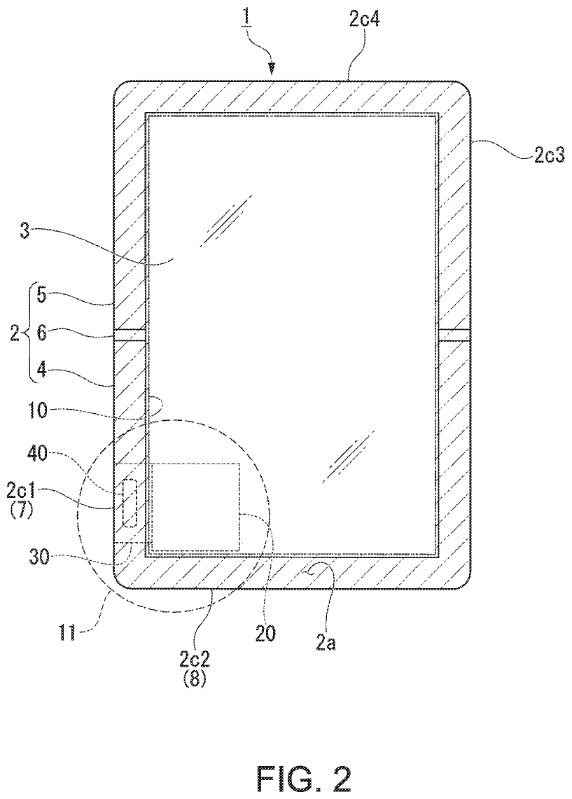

FIG. 1 is a perspective view of an electronic apparatus 1 according to the embodiment of the present invention. FIG. 2 is a plan view of the electronic apparatus 1 shown in FIG. 1 when its chassis 2 extends at an angle of 180 degrees.

As shown in these drawings, the electronic apparatus 1 includes the chassis 2 that can be folded in two and a flexible display 3 that can be folded in two together with the chassis 2.

The electronic apparatus 1 in the present embodiment is a clamshell personal computer (a so-called laptop personal computer) without a physical keyboard. The flexible display 3 is, for example, a touch-panel organic EL display or the like, and substitutes for a physical keyboard. It is to be noted that the electronic apparatus 1 may be a tablet, a cell-phone, a smartphone, an electronic organizer, or the like.

The chassis 2 includes a first chassis 4, a second chassis 5, and a hinge 6. The first chassis 4 and the second chassis 5 are each formed into a rectangular box-like shape, and their respective sides adjacent to each other are connected through the hinge 6. The first chassis 4 and the second chassis 5 can be open and closed at an angle ranging from 0 degrees (a storage form) to 180 degrees (a tablet form shown in FIG. 2) centering around the hinge 6.

The chassis 2 supports the flexible display 3 on its front surface 2a to be folded. A back surface 2b of the chassis 2 on the side opposite to the front surface 2a is provided with a cover (not shown) that protects the back surface 2b of the chassis 2, for example, when the chassis 2 extends at an angle of 180 degrees and is used in the tablet form.

A cooling fan 20 and a duct 30 which are described later, a motherboard, a sub-board, a communication module, a battery, etc. which are not shown in the drawings are housed in the chassis 2. The chassis 2 has four side surfaces (a first side surface 2c1, a second side surface 2c2, a third side surface 2c3, and a fourth side surface 2c4) in the plan view shown in FIG. 2. Of these four side surfaces, the first side surface 2c1 is provided with an air outlet 7 as shown in FIG. 1. Furthermore, an air intake 8 is provided on the second side surface 2c2 of the chassis 2 that is a different side surface from the first side surface 2c1.

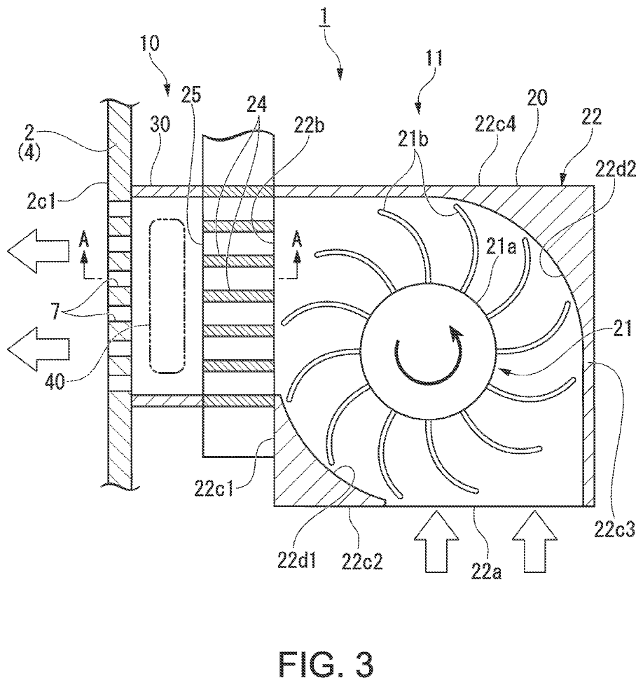

As shown in FIG. 1, the air outlet 7 is formed on a portion of the first side surface 2c1, and communicates with the duct 30. Meanwhile, the air intake 8 is formed over the entire second side surface 2c2. It is to be noted that except for a portion facing an air intake 22a of the cooling fan 20 to be described later (see FIG. 3), the air intake 8 may as well be a dummy air intake (an air intake formed for a reason of a design).

As shown in FIG. 2, the cooling fan 20 is disposed in a corner 11 of the chassis 2 formed by the first side surface 2c1 and the second side surface 2c2. As described above, the back surface 2b of the chassis 2 is provided with the cover (not shown), and thus an air intake cannot be provided on the back surface 2b. Accordingly, the cooling fan 20 has a structure of taking in air from the second side surface 2c2 and out the air from the first side surface 2c1 (a side to side fan).

In a peripheral edge 10 of the chassis 2 indicated by alternate long and two short dashes lines in FIG. 2, electronic components are densely disposed. These electronic components include, for example, various antennas (including a LAN antenna and a WAN antenna), I/O ports, a speaker, etc. The cooling fan 20 is disposed in the corner of the chassis 2 on the inner side rather than the peripheral edge 10 of the chassis 2 to avoid interference with these electronic components.

Meanwhile, so as not to hinder an exhaust air flow of the cooling fan 20, it is necessary to ensure a space leading to the air outlet 7 of the chassis 2 through the peripheral edge 10 of the chassis 2. Thus, the duct 30 lies between an air outlet of the cooling fan 20 and the air outlet 7 of the chassis 2. One (an electronic component 40) of the electronic components disposed in the peripheral edge 10 of the chassis 2 is mounted on the duct 30.

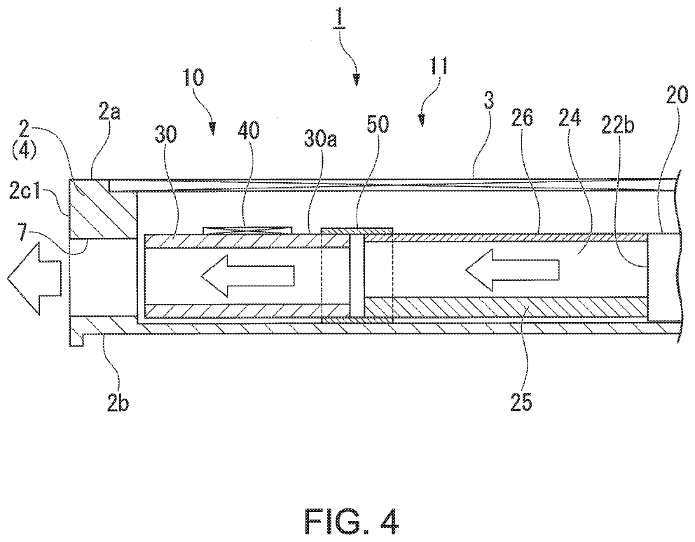

FIG. 3 is a cross-sectional plan view showing respective configurations of the cooling fan 20 and the duct 30 in the embodiment of the present invention. FIG. 4 is a view on an arrow A-A shown in FIG. 3.

As shown in FIG. 3, the cooling fan 20 includes a fan 21 and a fan casing 22.

The fan 21 includes a hub 21a that rotates around a central shaft and a plurality of blades 21b provided on the outer periphery of the hub 21a. The hub 21a is formed into a shape of a closed-top tube, and is connected to a motor (not shown) fixed to the fan casing 22. The plurality of blades 21b is curved to one side in a rotation direction of the hub 21a (in an example shown in FIG. 3, in a counterclockwise direction) viewed from an axial direction in which the central shaft of the hub 21a extends.

The fan casing 22 is formed into a rectangular box-like shape in plan view, and encloses the fan 21. The fan casing 22 has four side surfaces (a first side surface 22c1, a second side surface 22c2, a third side surface 22c3, and a fourth side surface 22c4). Of these four side surfaces, the first side surface 22c1 is provided with an air outlet 22b. Furthermore, the second side surface 22c2 is provided with the air intake 22a.

A first inner surface 22d1 of the fan casing 22 in a corner formed by the first side surface 22c1 and the second side surface 22c2 is curved along a rotation trajectory of distal ends of the blades 21b of the fan 21. Furthermore, a second inner surface 22d2 of the fan casing 22 located diagonally to the first inner surface 22d1 of the fan casing 22 is also curved along the rotation trajectory of the distal ends of the blades 21b of the fan 21.

The air outlet 22b is provided with a plurality of radiating fins 24. The plurality of radiating fins 24 extends parallel to the exhaust air flow of the cooling fan 20. The plurality of radiating fins 24 is thermally connected to a heat pipe 25. The heat pipe 25 is thermally connected to a heat-generating component such as a CPU of the motherboard (not shown).

As shown in FIG. 4, the plurality of radiating fins 24 is connected to a connecting plate 26 on the side opposite to the heat pipe 25, and forms a duct. The above-described duct 30 is disposed between the plurality of radiating fins 24 serving as a duct and the air outlet 7 of the chassis 2. The duct 30 guides the flow of exhaust air that has passed through gaps between the radiating fins 24 to the air outlet 7 of the chassis 2. It is to be noted that in a case where there is a gap (not shown in FIG. 3) between the plurality of radiating fins 24 serving as a duct and the duct 30 as shown in FIG. 4, the gap may be sealed with a sealing member 50 (a gasket, a tape, or the like).

The duct 30 is, for example, a rectangular tube-like plastic part, and is disposed in the peripheral edge 10 of the chassis 2 along the first side surface 2c1. As shown in FIG. 4, the electronic component 40 is mounted on an outer surface 30a of the duct 30. The electronic component 40 in the present embodiment is a planar wireless LAN antenna. Specifically, the wireless LAN antenna is an FPC antenna attached to the plastic duct 30. Furthermore, the wireless LAN antenna may be an antenna pattern formed directly on the duct 30 by laser direct structuring (LDS).

Moreover, for example, a microstrip antenna can be used as the wireless LAN antenna. It is to be noted that this microstrip antenna may be an antenna pattern formed on the duct 30 as a dielectric substrate. Furthermore, the wireless LAN antenna is not limited to a microstrip antenna, and may be, for example, a chip antenna or the like as long as it is thin.

As shown in FIGS. 3 and 4, the electronic apparatus 1 configured as described above includes the chassis 2 with the air outlet 7 provided on the first side surface 2c1, the cooling fan 20 housed in the chassis 2, the duct 30 lying between the air outlet 22b of the cooling fan 20 and the air outlet 7 of the chassis 2, and the electronic component 40 mounted on the duct 30; therefore, the duct 30 can be installed without changing the layout of the electronic component 40.

The electronic component 40 in the present embodiment is a planar wireless LAN antenna, which means the electronic component 40 is thin and can be provided on the outer surface 30a of the duct 30. Accordingly, the electronic component 40 can avoid hindering the exhaust air flow of the cooling fan 20 while ensuring the function as a wireless LAN antenna. It is to be noted that the wireless LAN antenna in the present embodiment is provided on the outer surface 30a of the duct 30 as a matter of convenience of manufacture; however, there is no functional problem if it is provided on an inner surface of the duct 30.

Furthermore, in the present embodiment, the air intake 8 is provided on the second side surface 2c2 of the chassis 2 that is a different side surface from the first side surface 2c1; therefore, even the thin electronic apparatus 1, which is unable to have an air intake on the back surface 2b of the chassis 2, can cool the inside of the chassis 2.

Moreover, the cooling fan 20 in the present embodiment is disposed in the corner 11 of the chassis 2 formed by the first side surface 2c1 and the second side surface 2c2; therefore, it requires less space for the cooling fan 20 to take air in and out.

Furthermore, the duct 30 and the electronic component 40 in the present embodiment are disposed in the peripheral edge 10 of the chassis 2 along the first side surface 2c1; therefore, the duct 30 can be installed without changing the layout of the electronic component 40 and other electronic components disposed in the peripheral edge 10.

Therefore, according to the present embodiment, it is possible to achieve the electronic apparatus 1 that does not hinder the exhaust air flow of the cooling fan 20 while easing restrictions on the freedom of layout of the electronic components in the peripheral edge 10 of the chassis 2.

The embodiment of the present invention is described in detail above with reference to the drawings; however, a specific configuration is not limited to the foregoing embodiment, and a design, etc. may be modified without departing from the scope of the invention. The configurations described in the foregoing embodiment can be combined arbitrarily as long as it does not contradict the nature of the invention.

For example, in the foregoing embodiment, a planar wireless LAN antenna is used as an example of the electronic component 40 mounted on the duct 30; however, as long as it is a thin component, the electronic component 40 may be an electronic component other than the wireless LAN antenna (a wireless WAN antenna, an mmWave antenna, or an electronic component other than an antenna).

Furthermore, for example, in the foregoing embodiment, a lateral air intake and exhaust structure shown in FIG. 3 is adopted as an example of the cooling fan 20; however, the present invention can be applied to not only this configuration but also a general centrifugal fan.

Moreover, for example, in the foregoing embodiment, there is described the electronic apparatus 1 including the chassis 2 that can be folded in two an example; however, the present invention can be applied to an unfoldable electronic apparatus as well.

1. An electronic apparatus comprising:
a chassis with an air outlet on a first side surface thereof;
a cooling fan housed in the chassis;
a duct lying between an air outlet of the cooling fan and the air outlet of the chassis; and
an electronic component mounted on the duct.

2. The electronic apparatus according to claim 1, wherein the electronic component is a planar wireless LAN antenna.

3. The electronic apparatus according to claim 1, wherein an air intake is on a second side surface of the chassis.

4. The electronic apparatus according to claim 3, wherein the cooling fan is disposed in a corner of the chassis formed by the first side surface and the second side surface.

5. The electronic apparatus according to claim 1, wherein the duct and the electronic component are disposed in a peripheral edge of the chassis along the first side surface.
